(19) United States
(12) Patent Application Publication
(10) Pub. No.: US 2011/0001210 A1
(43) Pub. Date: Jan. 6, 2011

(54) FUSE PART IN SEMICONDUCTOR DEVICE AND METHOD FOR FABRICATING THE SAME

(76) Inventor: Weon-Chul Jeon, Gyeonggi-do (KR)

Correspondence Address: IP & T GROUP LLP, 7700 Little River Turnpike, Suite 207, Annandale, VA, 22003, US

(21) Appl. No.: 12/640,350

(22) Filed: Dec. 17, 2009

(30) Foreign Application Priority Data
Jul. 3, 2009 (KR) 10-2009-0060545

(51) Int. Cl. H01L 29/66; H01L 21/44

(52) U.S. Cl. 257/529; 438/601; 257/E21.476; 257/E29.166

(57) ABSTRACT

A fuse part in a semiconductor device includes a conductive pattern formed over a substrate, wherein the conductive pattern includes a blowing part and a pad part, making contact with both sides of the blowing part and having a larger thickness than that of the blowing part, a protection layer formed over the substrate having the conductive pattern, and a fuse box formed in the protection layer located on an upper portion of the blowing part, wherein a portion of the protection layer maintains a certain thickness over the blowing part.

### CROSS-REFERENCE TO RELATED APPLICATIONS

The present application claims priority of Korean Patent Application No. 10-2009-0060545, filed on Jul. 3, 2009, which is incorporated herein by reference in its entirety.

### BACKGROUND OF THE INVENTION

Exemplary embodiments of the present invention relate to a method for fabricating a semiconductor device, and more particularly, to a fuse part in a semiconductor device which can prevent failure of a repair fuse and a method for fabricating the same.

When a semiconductor memory device is fabricated, one defective cell out of numerous micro cells results in the semiconductor memory device being discarded as an inferior device because the semiconductor memory device will not be able to execute a sufficient level of performance as a memory. However, it is very uneconomical to discard the entire device for having few defective cells in the memory. Thus, redundancy cells, which are prepared beforehand in the memory, are currently being used to perform a repairing process for replacing the defective cells. In this way, yield is improved because the entire memory is resuscitated. The semiconductor memory device includes a fuse part for the purpose of replacing the defective cells with the redundancy cells. A laser is applied to a fuse connected to the defective cell, and thus, a repairing process is performed by using a fuse blowing method that cuts the fuse.

Generally, the fuse is not formed by performing a separating process, but rather, is formed by extending a portion of an existing metal line. Copper (Cu) has a specific resistance lower than aluminum (Al) or tungsten (W), and copper can improve a signal propagation characteristic. Therefore, the metal lines are formed using copper, and the fuse is formed using copper metal lines.

FIG. 1 illustrates a plan view of a fuse part in a typical semiconductor device. FIGS. 2A to 2B are cross-sectional views taken along a line I-I′ of the typical semiconductor device shown in FIG. 1, and illustrate a method for fabricating the typical semiconductor device. FIG. 2C is a cross-sectional view taken along a line I-I′ of the is typical semiconductor device shown in FIG. 1, and illustrates a repairing method of the typical semiconductor device. Also, FIG. 3 illustrates reasons for concern regarding a fuse part in the typical semiconductor device.

Referring to FIG. 2A, a substrate 11 has a plurality of plugs 12 which connect a fuse and structures are formed in the substrate 11. An insulation layer 13 is formed over the substrate 11, and the insulation layer 13 is selectively etched to form a damascene pattern 14 exposing the plugs 12.

Referring to FIG. 2B, a metal layer is deposited to fill the damascene pattern 14. The metal layer includes copper (Cu). Then, the metal layer is planarized to expose the top surface of the insulation layer 13, and consequently, a fuse 15 is formed to fill the damascene pattern 14.

Next, a protection layer 16 is formed over the insulation layer 13 and the fuse 15. The protection layer 16 is selectively etched to form a fuse box 17 which represents a fuse open region. A portion of the protection layer 16 remains to a certain thickness W over the fuse 15 after the fuse box 17 is formed.

According to the typical repairing method, a repairing target fuse 15 is selected through a test, and a laser is applied to the repairing target fuse 15 to cut the fuse 15.

However, when a high acceleration stress test (HAST) is performed after the repairing process, the cut fuse 15′ is electrically re-connected as shown by region ‘A’ in FIG. 2C due to environmental elements of the test (e.g., temperature, humidity and applying voltage). Such failure to repair the fuse reduces the yield and reliability of the semiconductor device.

Particularly, under the test environment which controls the temperature and the humidity conditions, the exposed sidewalls S of the cut fuse 15′ (i.e., the repair fuse 15) are oxidized, and a conductive oxide-based material is formed. The conductive oxide-based material is gradually grown and the cut fuse 15′ is electrically re-connected. Also, under the test environment, which controls the voltage condition or the temperature condition, migrations (e.g., an electro migration (EM) and a stress migration (SM)) occur on the cut fuse 15′, thereby electrically re-connecting the cut fuse 15′.

Because the fuse 15 is formed by extending a portion of an existing metal line, the thickness of the fuse 15 is great. Therefore, since the area of the sidewalls S of the cut fuse 15′ is relatively wide, reactions with oxygen and migrations occur easily during the test. Thus, the typical semiconductor device has the above limitations.

### SUMMARY OF THE INVENTION

An embodiment of the present invention is directed to a fuse part in a semiconductor device which can prevent failure of a repair fuse (i.e., an electrical re-connection of a cut fuse) after a repairing process, and a method for fabricating the same.

In accordance with an embodiment of the present invention, a fuse part in a semiconductor device includes a conductive pattern formed over a substrate, wherein the conductive pattern includes a blowing part and a pad part, making contact with both sides of the blowing part and having a larger thickness than that of the blowing part, a protection layer formed over the substrate having the conductive pattern, and a fuse box formed in the protection layer located on an upper portion of the blowing part, wherein a portion of the protection layer maintains a certain thickness over the blowing part.

In accordance with another embodiment of the present invention, a fuse part in a semiconductor device includes a conductive pattern formed over a substrate, wherein the conductive pattern includes a blowing part, a pad part aligned at both sides of the blowing part, and a connection part connected between the blowing part and the pad part and having a smaller thickness than that of the blowing part, a protection layer formed over the substrate having the conductive pattern, and a fuse box formed in the protection layer located on an upper portion of the blowing part, wherein a portion of in the protection layer maintains a certain thickness over the blowing part.

In accordance with yet another embodiment of the present invention, a method for fabricating a fuse in a semiconductor device includes forming a conductive pattern over a substrate, wherein the conductive pattern includes a blowing part and a pad part, making contact with both sides of the blowing part and having a larger thickness than that of the blowing part, forming a protection layer over the substrate having the conductive pattern, and selectively etching the protection layer to form a fuse box located on an upper portion of the blowing part, wherein a portion of the protection layer maintains a certain thickness over the blowing part.

In accordance with still another embodiment of the present invention, a method for fabricating a fuse in a semiconductor device includes forming a conductive pattern over a substrate, wherein the conductive pattern includes a blowing part, a pad part aligned at both sides of the blowing part, and a connection part connecting the blowing part and the pad part and having a smaller thickness than that of the blowing part, forming a protection layer over the substrate having the conductive pattern, and selectively etching the protection layer to form a fuse box located on an upper portion of the blowing part, wherein a portion of the protection layer maintains a certain thickness over the blowing part.

### BRIEF DESCRIPTION OF THE DRAWINGS

FIG. 1 illustrates a plan view of a fuse part in a typical semiconductor device.

FIGS. 2A to 2B are cross-sectional views taken along a line I-I′ of the typical semiconductor device shown in FIG. 1, and illustrate a method for fabricating the typical semiconductor device.

FIG. 2C is a cross-sectional view taken along a line I-I′ of the typical semiconductor device shown in FIG. 1, and illustrates a repairing method of the typical semiconductor device.

FIG. 3 illustrates reasons for concern regarding a fuse part in the typical semiconductor device.

FIGS. 4A to 4C illustrate a fuse part of a semiconductor device in accordance with a first embodiment of the present invention.

FIGS. 5A to 5C illustrate a fuse part of a semiconductor device in accordance with a second embodiment of the present invention.

FIGS. 6A to 6C are cross-sectional views illustrating a method for fabricating the fuse part of the semiconductor device shown in FIG. 5A.

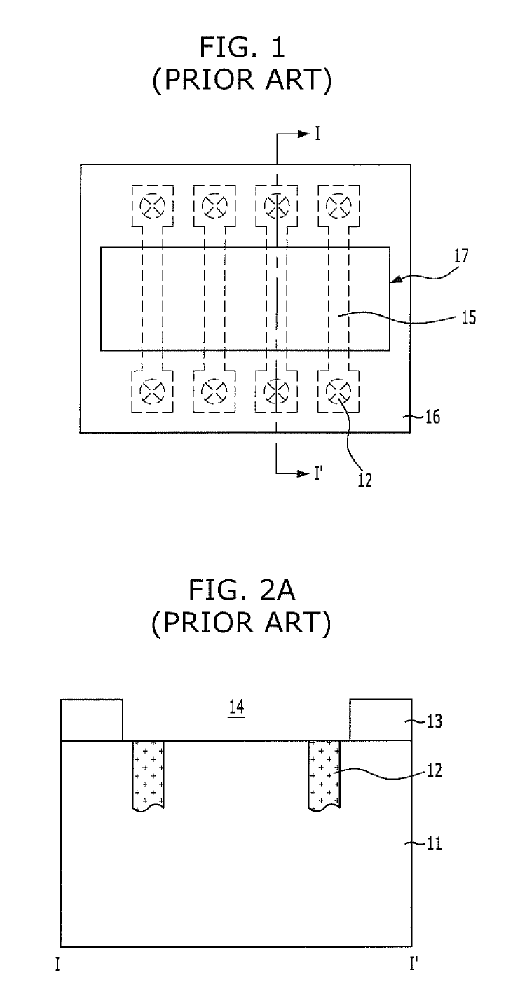

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it may not only refer to a case where the first layer is formed directly on the second layer or the substrate, but also may refer to a case where a third layer exists between the first layer and the second layer or the substrate.

Hereinafter, some embodiments are directed to a fuse part in a semiconductor device which can prevent failure of a repair fuse and a method for fabricating the same. Herein, the failure of the repair fuse means a cut fuse is electrically re-connected during a subsequent test after a repairing process.

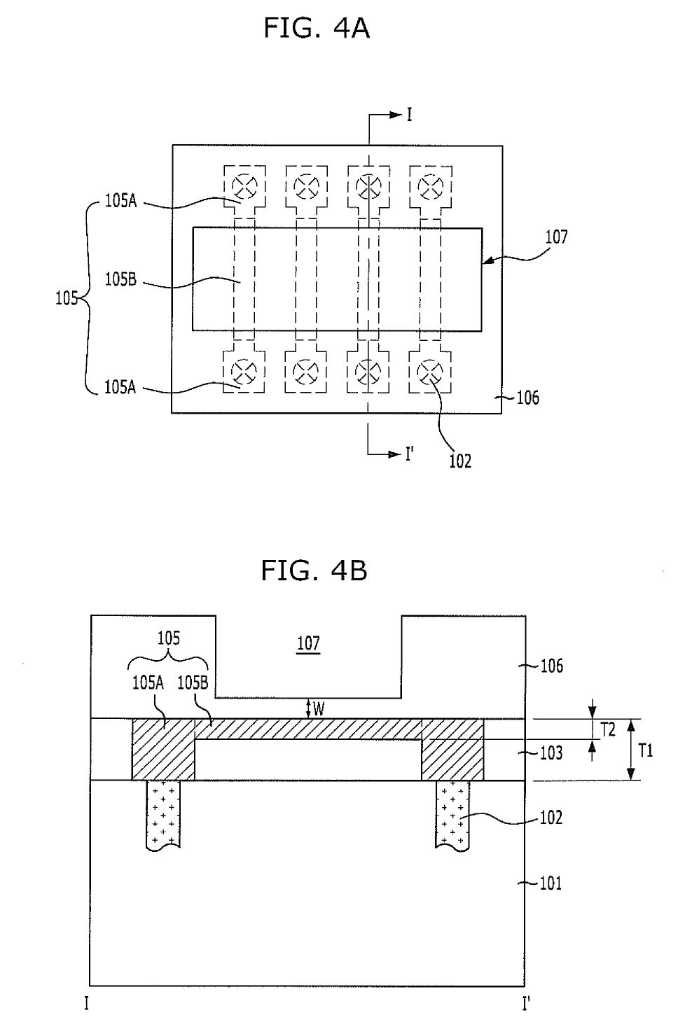

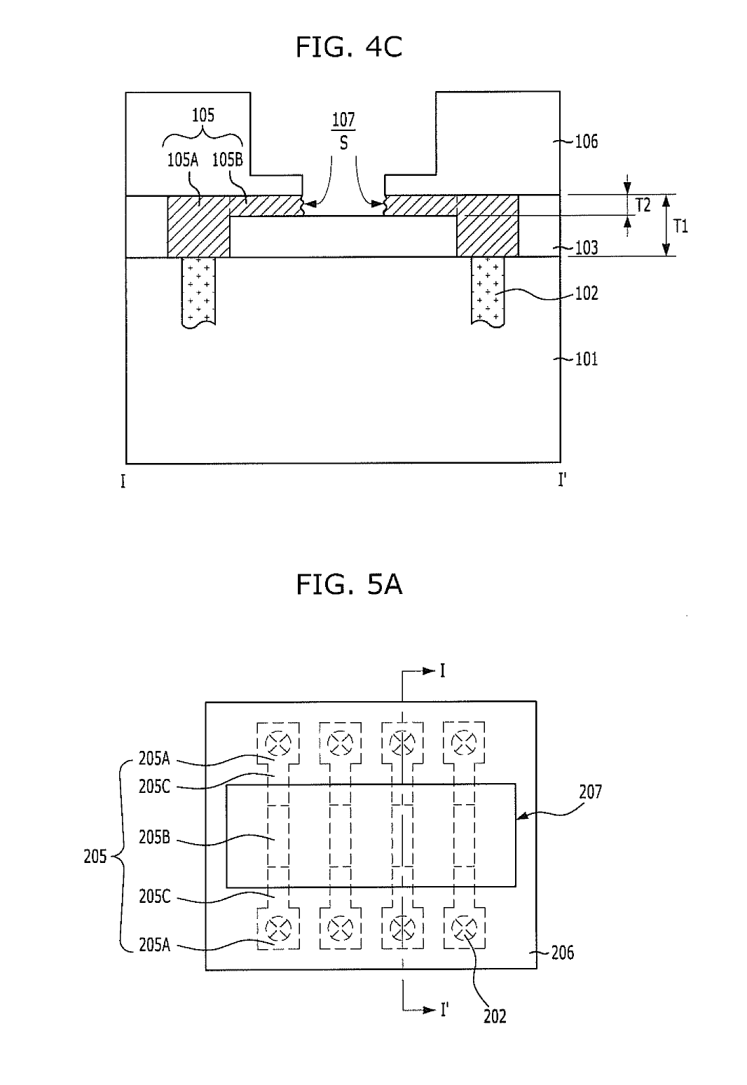

FIGS. 4A to 4C illustrate a fuse part of a semiconductor device in accordance with a first embodiment of the present invention. FIG. 4A is a plan view of the semiconductor device; FIG. 4B is a cross-sectional view taken along a line I-I′ of the semiconductor device shown in FIG. 4A; and FIG. 4C is a cross-sectional view taken along the line I-I′ of the semiconductor device shown in FIG. 4A illustrating the semiconductor device having a cut fuse.

As shown in FIGS. 4A and 4B, the fuse part of the semiconductor device in accordance with the first embodiment of the present invention includes a conductive pattern 105, a protection layer 106, and a fuse box 107.

The conductive pattern 105 includes a blowing part 105B formed over a substrate 101 with a predetermined structure, and a pad part 105A making contact with both sides of the blowing part 105B and having a larger thickness than a thickness of the blowing part 105B. The thickness of the blowing part 105B is denoted as T2, and the thickness of the pad part 105A is denoted as T1. As shown in FIG. 4B, T1 is greater than T2 (T1>T2).

The protection layer 106 is formed over the substrate 101 having the conductive pattern 105. The protection layer 106 is selectively etched to form a fuse box 107, which represents a fuse open region. That is, the fuse box 107 is formed in the protection layer 106.

In order to protect the conductive pattern 105 exposed by the fuse box 107, a portion of the protection layer 106 maintains a certain thickness W over the conductive pattern 105 after the fuse box 107 is formed. That is, the portion of the protection layer 106 protects the conductive pattern 105. Particularly, the protection layer 106 prevents an oxidation of the conductive pattern 105, an impact caused by a blowing of an adjacent fuse during a repairing process, and damages or failure by a conductive by-product.

The fuse part further includes a contact part 102 making contact with an upper portion or a lower portion of the pad part 105A. According to the first embodiment, the contact part 102 making contact with the lower portion of the pad part 105A is illustrated in FIGS. 4A to 4B. However, the contact part 102 may contact the upper portion of the pad part 105A in some cases.

The conductive pattern 105, including the pad part 105A and the blowing part 105B, acts as a fuse. The conductive pattern 105 is a line-type pattern having the pad part 105A, the blowing part 105B, and the pad part 105A aligned in sequence. The pad part 105A is a region for electrically connecting the conductive pattern 105 with the upper structure or the lower structure. The blowing part 105B, located between the pad part 105A, is a region for applying a laser in the repairing process. Since the thickness T2 of the blowing part 105B is smaller than the thickness T1 of the pad part 105A, the area of the sidewalls S of the cut fuse is decreased after the repairing process is performed. Therefore, the failure of the repair fuse is prevented.

When the conductive pattern 105 is formed by extending a portion of an existing metal line, the thickness T1 of the pad part 105A is the same as the thickness of the metal line, while the thickness T2 of the blowing part 105B is smaller than the thickness of the metal line.

The conductive pattern 105 includes a metal layer. For example, the conductive pattern 105 may include copper (Cu), aluminum (Al), cobalt (Co), tungsten (W), or tantalum (Ta). Copper (Cu) has a specific resistance lower than other metal layers and copper can improve a signal propagation characteristic. Therefore, the conductive pattern 105 is preferably formed with copper.

The protection layer 106 is formed of one selected from a group consisting of an oxide layer, a nitride layer, an oxynitride layer, an amorphous carbon layer, a polyimide, and the combination thereof. That is, the protection layer 106 may include a single layer or a stacked structure.

In the fuse part according to the first embodiment, as the blowing part 105B, having a smaller thickness than the pad part 105A, is cut during the repairing process, an electrical re-connection of the cut fuse is prevented during a subsequent test. Hereinafter, prevention of a repair fuse failure will be described in detail by referring to FIG. 4C.

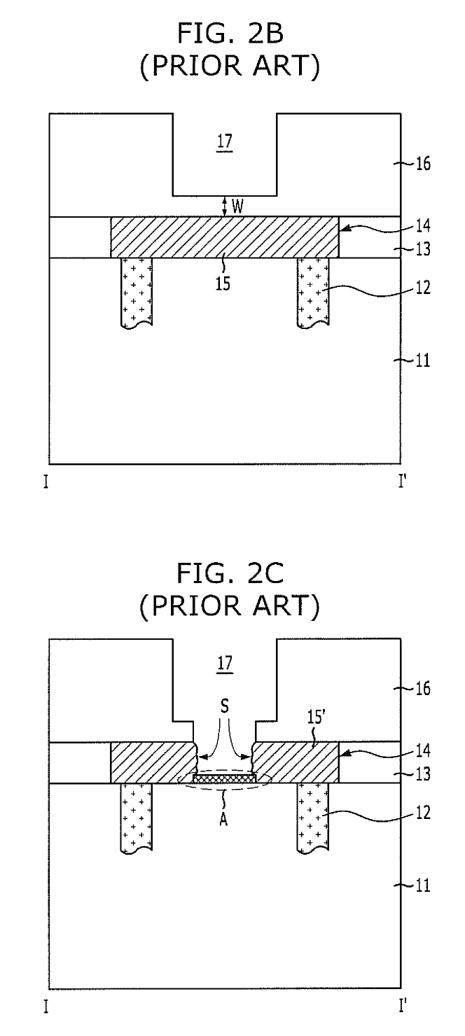

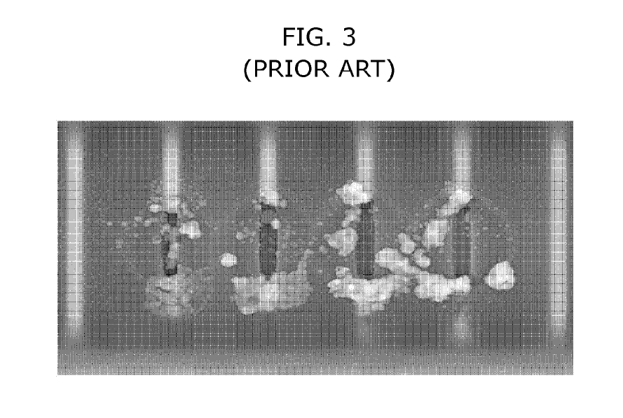

A fuse of the typical fuse part is a conductive pattern having a constant thickness. Accordingly, when the typical fuse part is cut, during the repairing process, the area of the sidewalls of the cut fuse is relatively large. When a high acceleration stress test (HAST) is performed after the repairing process, the cut fuse is electrically re-connected due to environment elements of the test (e.g., temperature, humidity, and voltage). Therefore, the failure of the repair fuse (i.e., the cut fuse) occurs as shown in FIGS. 2C and 3.

On the contrary, referring to FIG. 4C, the fuse in accordance with the first embodiment is formed of the conductive pattern 105, including the pad part 105A and the blowing part 105B having different thicknesses than each other. Therefore, when the blowing part 105B, having a smaller thickness than the pad part 105A, is cut during the repairing process, the area of the exposed fuse (i.e., the area of the sidewalls S of the cut fuse) is less than the typical cut fuse.

As described above, because the area of the sidewalls S of the cut fuse is reduced, reaction with oxygen and occurrence of migrations are prevented in the test environment, where temperature, humidity, and applying voltage are adjusted. Therefore, the failure of the repair fuse may be prevented.

Hereinafter, a second embodiment with an improved signal propagation characteristic of the fuse is described.

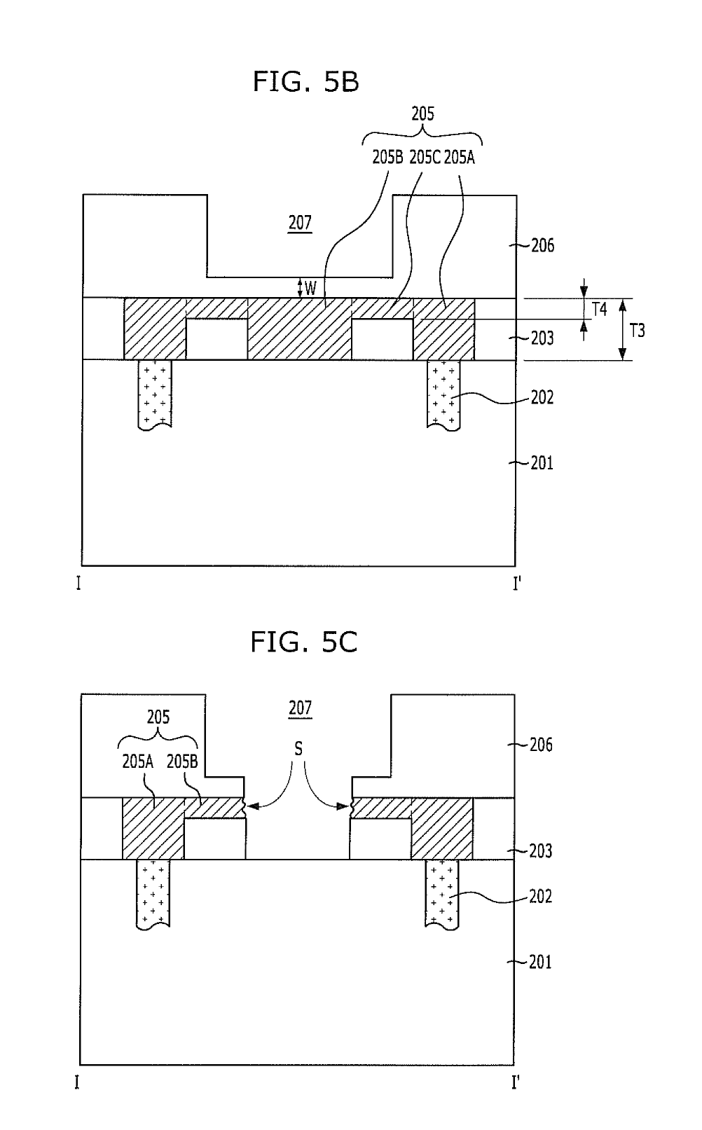

FIGS. 5A to 5C illustrate a fuse part of a semiconductor device in accordance with a second embodiment of the present invention. FIG. 5A is a plan view of the semiconductor device; FIG. 5B is a cross-sectional view taken along a line I-I′ of the semiconductor device shown in FIG. 5A; and FIG. 5C is a cross-sectional view taken along the line I-I′ of the semiconductor device shown in FIG. 5A illustrating the semiconductor device having a cut fuse.

As shown in FIGS. 5A and 5B, the fuse part of the semiconductor device in accordance with the second embodiment of the present invention includes a conductive pattern 205, a protection layer 206, and a fuse box 207.

The conductive pattern 205 includes a blowing part 205B formed over a substrate 201 with a predetermined structure, a pad part 205A aligned at the both sides of the blowing part 205B, and a connection part 205C connecting the blowing part 205B and the pad part 205A and having a smaller thickness than a thickness of the blowing part 205B. The thickness of the blowing part 205B is denoted as T3, and the thickness of the connection part 205C is denoted as T4. As shown in FIG. 5B, T3 is greater than T4 (T3>T4).

The protection layer 206 is formed over the substrate 201 having the conductive pattern 205. The protection layer 206 is selectively etched to form a fuse box 207, which represents a fuse open region. That is, the fuse box 207 is formed in the protection layer 206. In order to protect the conductive pattern 205 exposed by the fuse box 207, a portion of the protection layer 206 maintains a certain thickness W over the conductive pattern 205 after the fuse box 207 is formed.

The fuse part further includes a contact part 202 making contact with an upper portion or a lower portion of the pad part 205A. According to the second embodiment, the contact part 202 making contact with the lower portion of the pad part 205A is illustrated in FIGS. 5A to 5B. However, the contact part 202 may contact the upper portion of the pad part 205A in some cases.

The conductive pattern 205, including the pad part 205A, the blowing part 205B, and the connection part 205C, acts as a fuse. The conductive pattern 205 is a line-type pattern having the pad part 205A, the connection part 205C, the blowing part 205B, the connection part 205C, and the pad part 205A aligned in sequence.

The pad part 205A is a region for electrically connecting the conductive pattern 205 with the upper structure or the lower structure. The blowing part 205B located between the connection part 205C is a region for applying a laser in the repairing process. Since the thickness T4 of the connection part 205C is smaller than the thickness T3 of the blowing part 205B, the area of the sidewalls S of the cut fuse is relatively small after the repairing process is performed. Therefore, the failure of the repair fuse is prevented.

When the conductive pattern 205 is formed by extending a portion of an existing metal line, the thickness T3 of the pad part 205A and blowing part 205B is the same as the thickness of the metal line, while the thickness T4 of the connection part 205C is smaller than the thickness of the metal line.

In the first embodiment, the blowing part 105B is a region having a smaller thickness, but in the conductive pattern 205 of the second embodiment, the connection part 205C is a region having a smaller thickness. The connection part 205C constitutes a smaller percentage of the conductive pattern 205 than the blowing part 105B constitutes of the conductive pattern 105. Because the total resistance of the conductive pattern 205 in accordance with the second embodiment is smaller than that of the conductive pattern 105 in accordance with the first embodiment, a circuit driving capacity of the second embodiment may improved over that of the first embodiment.

In the fuse part according to the second embodiment, when the repairing process is performed, the blowing part 2056 is removed, and the connection part 205C, connecting both sides of the blowing part 205B and having a smaller thickness than the blowing part 205B, is exposed. The smaller thickness of the connection part 205C means that the area of the sidewall surfaces, exposed as a result of the repairing process, is smaller. Further, the smaller surface area of the exposed sidewalls of the conductive pattern 205 prevents an electrical re-connection of the cut fuse, which might otherwise occur in a subsequent test. Hereinafter, prevention of a repair fuse failure will be described in detail by referring to FIG. 5C.

Referring to FIG. 5C, the fuse in accordance with the second embodiment is formed of the conductive pattern 205 including the pad part 205A, the blowing part 205B, and the connection part 295C having a smaller thickness than both the pad part 205A and the blowing part 205B. As the blowing part 205B is removed, the sidewalls of the connection part 205C, having the smallest thickness in the conductive pattern 205, are exposed after the repairing process. Therefore, the area of the exposed fuse (i.e., the area of the sidewalls S of the cut fuse) is reduced. Because the area of the sidewalls S of the cut fuse is reduced, reaction with oxygen and occurrence of migrations are prevented in the test environment where the temperature, humidity, and applying voltage are adjusted. Therefore, the failure of the repair fuse may be prevented.

Hereinafter, a method for fabricating the fuse part of the semiconductor device shown in FIGS. 5A and 5B will be described in detail. For example, in the semiconductor device having metal lines of a triple layer metal (TLM) structure (i.e., the semiconductor device including a first metal line, a second metal line, and a third metal line), a second metal line may be used as the fuse.

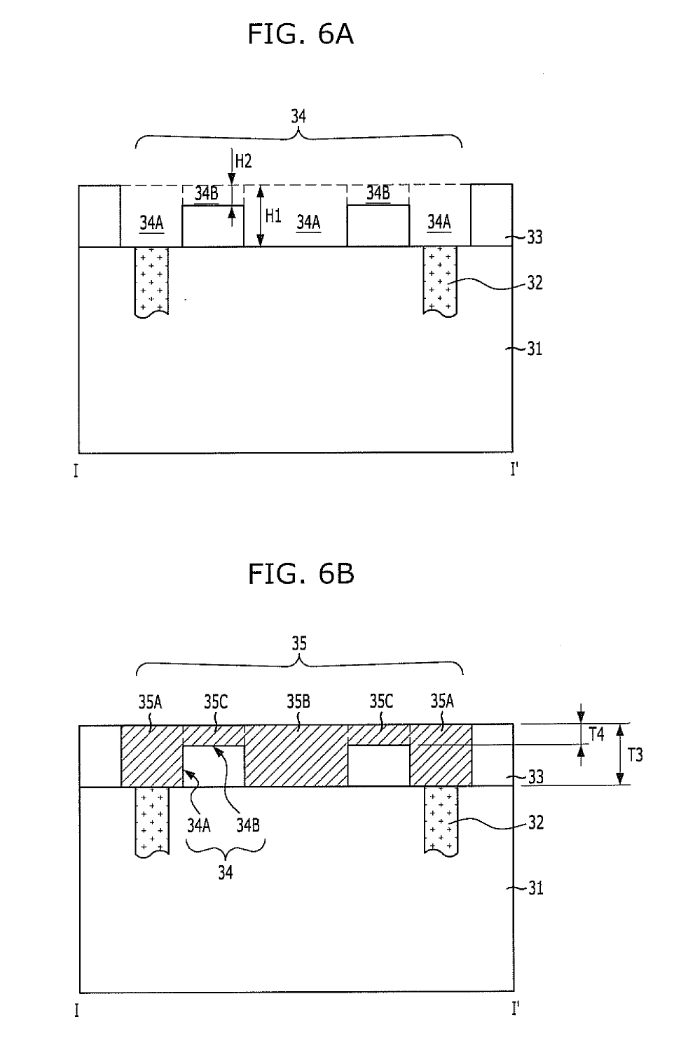

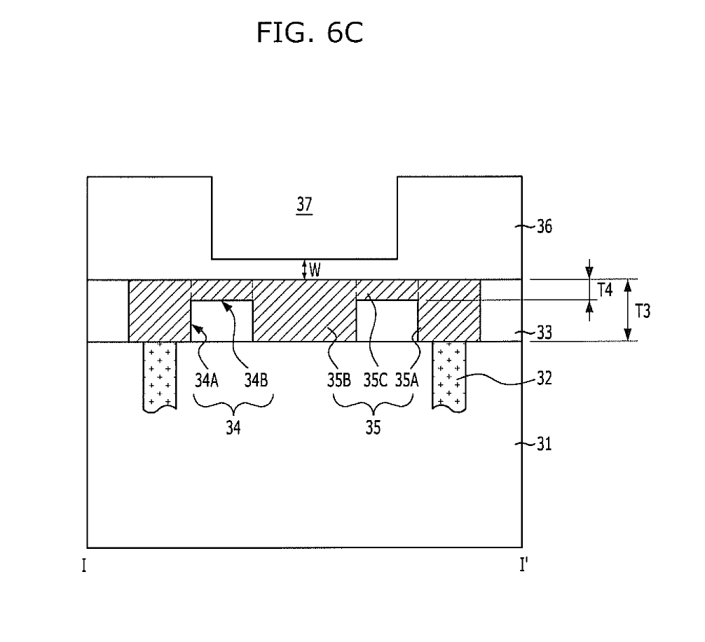

FIGS. 6A to 6C are cross-sectional views illustrating a method for fabricating the fuse part of the semiconductor device shown in FIGS. 5A and 5B.

Referring to FIG. 6A, a plurality of contact parts 32 are formed in a substrate 31 with a predetermined structure in order to electrically connect a fuse and a first metal line. An insulation layer 33 is formed over the substrate 31 having the contact parts 32. The insulation layer 33 is an inter-metal dielectric (IMD) used for isolating metal lines, and the insulation layer 33 is formed of on oxide layer.

By selectively etching the insulation layer 33, a plurality of first patterns 34A, having a first height H1 and exposing the upper surface of the contact parts 32 and the upper surface of the substrate 31, are formed in the insulation layer 33. Simultaneously, a plurality of second patterns 34B, having a second height H2 smaller than the first height H1, are formed between the first patterns 34A. Thus, a damascene pattern 34, including the first patterns 34A and the second patterns 34B, is formed.

The damascene pattern 34 is a region for forming the fuse. The damascene pattern 34 may be a line pattern, including the first pattern 34A and the second pattern 348 having different heights than each other, and the first pattern 34A and the second pattern 34B alternating with each other.

Referring to FIG. 6B, a conductive material is deposited to fill the damascene pattern 34 and to cover the insulation layer 33. A conductive pattern 35 is formed by performing a planarization process of the conductive material to expose the upper surface of the insulation layer 33. The planarization process may include a chemical mechanical planarization (CMP).

The conductive pattern 35 includes a pad part 35A, a blowing part 35B, and a connection part 35C. The pad part 35A is formed by filling the first patterns 34A exposing the upper surface of the contact parts 32. The blowing part 35B is formed by filling the first pattern 34A exposing the upper surface of the substrate 31. The connection part 35C is formed by filling the second pattern 34B. The conductive pattern 35 acts as a fuse. The conductive pattern 35 is a line-type pattern having the pad part 35A, the connection part 35C, the blowing part 35B, the connection part 35C, and the pad part 35A aligned in sequence. The pad part 35A is a region for electrically connecting the conductive pattern 35 with the upper structure or the lower structure. The blowing part 35B, located between the connection part 35C, is a region for applying a laser in the repairing process. Since the thickness T4 of the connection part 35C is smaller than the thickness T3 of the blowing part 35B, the area of the sidewalls S of the cut fuse is decreased after the repairing process is performed. Therefore, the failure of the repair fuse is prevented.

The pad part 35A, the blowing part 35B, and the connection part 35C are formed of the same material because the pad part 35A, the blowing part 35B, and the connection part 35C are formed simultaneously.

The conductive pattern 35 includes a metal layer. For example, the conductive pattern 35 may include copper (Cu), aluminum (Al), cobalt (Co), tungsten (W), or tantalum (Ta). Copper (Cu) has a specific resistance lower than other metal layers and copper can improve a signal propagation characteristic. Therefore, the conductive pattern 35 is preferably formed with copper.

Referring to FIG. 6C, a protection layer 36 is formed over the substrate structure having the conductive pattern 35. The protection layer 36 is formed of one selected from a group consisting of an oxide layer, a nitride layer, an oxynitride layer, an amorphous carbon layer, a polyimide, and the combination thereof. That is, the protection layer 36 may include a single layer or a stacked structure.

The protection layer 36 is selectively etched to form a fuse box 37, which represents a fuse open region. In order to protect the conductive pattern 35 exposed by the fuse box 37, a portion of the protection layer 36 maintains a certain thickness over the conductive pattern 35 by adjusting an etching recipe. The protection layer 36 prevents an oxidation of the conductive pattern 35, an impact caused by a blowing of an adjacent fuse during a repairing process, and damages during subsequent processes.

The fuse part in accordance with the second embodiment of the present invention may be formed, as described above. The method for fabricating the fuse part in accordance with the second embodiment is described with reference to FIGS. 6A to 6C, but the fuse part in accordance with the first embodiment is easily formed by applying the method for fabricating the fuse part in accordance with the second embodiment.

In the present invention, the conductive pattern is formed to have either a blowing part with a relatively small thickness, or a connection part connected to the blowing part with a relatively small thickness. After the fuse is cut, the sidewalls of the region having the smallest thickness among the regions of the conductive pattern are exposed. Since the area of the exposed conductive pattern (i.e., the area of the sidewalls S of the cut fuse) is reduced, reaction with oxygen and occurrence of migrations are prevented during a subsequent test/process.

The present invention improves the yield and reliability of the semiconductor device by preventing the failure of the repair fuse (i.e., an electrical re-connection of the cut fuse during a subsequent test/process).

While the present invention has been described with respect to the specific embodiments, it will be apparent to those skilled in the art that various changes and modifications may be made without departing from the spirit and scope of the invention as defined in the following claims.

What is claimed is:

1. A fuse part in a semiconductor device, comprising:
a conductive pattern formed over a substrate, wherein the conductive pattern includes a blowing part and a pad part, making contact with both sides of the blowing part and having a larger thickness than that of the blowing part;
a protection layer formed over the substrate having the conductive pattern; and
a fuse box formed in the protection layer located on an upper portion of the blowing part, wherein a portion of the protection layer maintains a certain thickness over the blowing part.

2. The fuse part in the semiconductor device of claim 1, further comprising:
a contact part making contact with an upper portion or a lower portion of the pad part.

3. The fuse part in the semiconductor device of claim 1, wherein the conductive pattern is a line-type pattern including the pad part, the blowing part, and the pad part aligned in sequence.

4. The fuse part in the semiconductor device of claim 1, wherein the conductive pattern includes copper.

5. A fuse part in a semiconductor device, comprising:
a conductive pattern formed over a substrate, wherein the conductive pattern includes a blowing part, a pad part aligned at both sides of the blowing part, and a connection part, connected between the blowing part and the pad part and having a smaller thickness than that of the blowing part;
a protection layer formed over the substrate having the conductive pattern; and
a fuse box formed in the protection layer located on an upper portion of the blowing part, wherein a portion of the protection layer maintains a certain thickness over the blowing part.

6. The fuse part in the semiconductor device of claim 5, further comprising:
a contact part making contact with an upper portion or a lower portion of the pad part.

7. The fuse part in the semiconductor device of claim 5, wherein the conductive pattern is a line-type pattern including the pad part, the connection part, the blowing part, the connection part, and the pad part aligned in sequence.

8. The fuse part in the semiconductor device of claim 5, wherein the conductive pattern includes copper.

9. A method for fabricating a fuse in a semiconductor device, comprising:
forming a conductive pattern over a substrate, wherein the conductive pattern includes a blowing part and a pad part, making contact with both sides of the blowing part and having a larger thickness than that of the blowing part;
forming a protection layer over the substrate having the conductive pattern; and
selectively etching the protection layer to form a fuse box located on an upper portion of the blowing part, wherein a portion of the protection layer maintains a certain thickness over the blowing part.

10. The method of claim 9, further comprising:
forming a contact part making contact with the pad part before the conductive pattern is formed.

11. The method of claim 9, further comprising:
forming a contact part making contact with the pad part after the conductive pattern is formed.

12. The method of claim 9, wherein the conductive pattern is a line-type pattern including the pad part, the blowing part, and the pad part aligned in sequence.

13. The method of claim 9, wherein the forming of the conductive pattern includes:
forming an insulation layer over the substrate;
forming a plurality of first patterns and a second pattern by selectively etching the insulation layer, wherein the second pattern connected with the first patterns is formed between the first patterns, and a height of the second pattern is a smaller than a height of the first patterns; and
depositing a conductive material to fill the first patterns and the second pattern.

14. The method of claim 9, wherein the conductive pattern includes copper.

15. A method for fabricating a fuse in a semiconductor device, comprising:
forming a conductive pattern over a substrate, wherein the conductive pattern includes a blowing part, a pad part aligned at both sides of the blowing part, and a connection part, connecting the blowing part and the pad part and having a smaller thickness than that of the blowing part;
forming a protection layer over the substrate having the conductive pattern; and
selectively etching the protection layer to form a fuse box located on an upper portion of the blowing part, wherein a portion of the protection layer maintains a certain thickness over the blowing part.

16. The method of claim 15, further comprising:
forming a contact part making contact with the pad part before the conductive pattern is formed.

17. The method of claim 15, further comprising:
forming a contact part making contact with the pad part after the conductive pattern is formed.

18. The method of claim 15, wherein the conductive pattern is a line-type pattern including the pad part, the connection part, the blowing part, the connection part, and the pad part aligned in sequence.

19. The method of claim 15, wherein the forming of the conductive pattern comprises:
forming an insulation layer over the substrate;
forming a plurality of first patterns and a plurality of second patterns by selectively etching the insulation layer, wherein the second patterns connected with the first patterns are formed between the first patterns, and heights of the second patterns are smaller than heights of the first patterns; and
depositing a conductive material to fill the first patterns and the second pattern.

20. The method of claim 15, wherein the conductive pattern includes copper.
